(19) United States
(12) Patent Application Publication
(10) Pub. No.: US 2016/0087126 A1
(43) Pub. Date: Mar. 24, 2016

(54) PHOTOELECTRIC CONVERSION DEVICE, SOLAR CELL AND METHOD FOR MANUFACTURING PHOTOELECTRIC CONVERSION DEVICE

(71) Applicant: Kabushiki Kaisha Toshiba, Minato-ku (JP)

(72) Inventors: Naoyuki NAKAGAWA, Setagaya (JP); Soichiro Shibasaki, Nerima (JP); Hiroki Hiraga, Kawasaki (JP); Hitomi Saito, Kawaguchi (JP); Mutsuki Yamazaki, Yokohama (JP); Kazushige Yamamoto, Yokohama (JP)

(73) Assignee: Kabushiki Kaisha Toshiba, Minato-ku (JP)

(21) Appl. No.: 14/854,170

(22) Filed: Sep. 15, 2015

(30) Foreign Application Priority Data
Sep. 22, 2014 (JP) 2014-192363

(51) Int. Cl. H01L 31/032; H01L 31/18

(52) U.S. Cl. CPC H01L 31/0322; H01L 31/18

(57) ABSTRACT

A photoelectric conversion device of an embodiment has a bottom electrode, a light absorbing layer on the bottom electrode. The light absorbing layer comprises a thin film of a semiconductor comprising a group Ib element or elements, a group IIIb element or elements, and a group VIb element or elements and having a chalcopyrite structure. The light absorbing layer has an average crystal grain size of 1.5 μm or more. The group IIIb element or elements include Ga, Al, or both of Ga and Al.

### CROSS-REFERENCE TO RELATED APPLICATION

This application is based upon and claims the benefit of priority from Japanese Patent Application No. 2014-192363 filed on Sep. 22, 2014; the entire contents of which are incorporated herein by reference.

### FIELD

Embodiments described herein relate to a photoelectric conversion device, a solar cell and a method for manufacturing photoelectric conversion device.

### BACKGROUND

Photoelectric conversion devices having a semiconductor thin film as a light absorbing layer have been developed. In particular, photoelectric conversion devices having, as a light absorbing layer, a p-type semiconductor layer with a chalcopyrite structure have high conversion efficiency and thus promising applications. Specifically, photoelectric conversion devices having a light absorbing layer of Cu(In,Ga)Se₂ as a Cu—In—Ga—Se (CIGS) compound have relatively high conversion efficiency. In addition, the band gap (Eg) can be widely modulated by selecting the constituent elements of chalcopyrite compound semiconductors.

A photoelectric conversion device has a p-type semiconductor layer of Cu—In—Ga—Se as a light absorbing layer. Such a photoelectric conversion device generally has a structure including a soda-lime glass substrate, and a bottom electrode, a p-type semiconductor layer, an n-type semiconductor layer, a transparent electrode, a top electrode, and an antireflective film, which are stacked on the substrate. A high-efficiency CIGS thin-film solar cell is also designed to have a homojunction structure in which a p-type semiconductor layer has an n-type doped part in the vicinity of an upper transparent electrode. The n-type doping is performed by a treatment in a solution after the p-type semiconductor layer is formed by vapor deposition or the like.

A high-efficiency CIGS solar cell can be obtained using a light absorbing layer of a p-type semiconductor thin film in which the CIGS composition has a stoichiometric to slight excess amount of the group III element. Such a CIGS solar cell is produced using a multi-source deposition method, specifically, a three-stage method. The three-stage method includes vapor-depositing In, Ga, and Se to form a (In,Ga)₂Se₃ film at the first stage, then supplying only Cu and Se to form a film with a Cu-excess composition (second stage), and finally supplying In, Ga, and Se fluxes again to form a film with a final (In,Ga)-excess composition (third stage). At the second stage, a Cu—Se-excess composition is temporarily produced, so that large-size grains are produced via the Cu—Se liquid phase, which reduces bulk defects in the light absorbing layer. When the constituent elements of the light absorbing layer do not include In as a group III element but include Al or Ga, the three-stage deposition method has difficulty in forming large-size grains for the light absorbing layer and can increase bulk defects because the diffusion coefficient of Al and Ga is smaller than that of In.

### BRIEF DESCRIPTION OF THE DRAWINGS

FIG. 1 is a schematic cross-sectional view of a photoelectric conversion device according to an embodiment;

FIG. 2 is a schematic cross-sectional view of a multi-junction photoelectric conversion device according to an embodiment;

FIG. 3 is a cross-sectional SEM image of a part including the light absorbing layer of a photoelectric conversion device according to Example 1;

FIG. 4 is a graph showing the results of SIMS analysis of the photoelectric conversion device according to Example 1;

FIG. 5 is a cross-sectional SEM image of a part including the light absorbing layer of a photoelectric conversion device according to Comparative Example 1; and

FIG. 6 is a graph showing the results of SIMS analysis of the photoelectric conversion device according to Comparative Example 1.

### DETAILED DESCRIPTION

A photoelectric conversion device of an embodiment has a bottom electrode, a light absorbing layer on the bottom electrode. The light absorbing layer comprises a thin film of a semiconductor comprising a group Ib element or elements, a group IIIb element or elements, and a group VIb element or elements and having a chalcopyrite structure. The light absorbing layer has an average crystal grain size of 1.5 μm or more. The group IIIb element or elements include Ga, Al, or both of Ga and Al.

A solar cell of an embodiment has a photoelectric conversion device. The photo electric conversion device has a bottom electrode, a light absorbing layer on the bottom electrode. The light absorbing layer comprises a thin film of a semiconductor comprising a group Ib element or elements, a group IIIb element or elements, and a group VIb element or elements and having a chalcopyrite structure. The light absorbing layer has an average crystal grain size of 1.5 μm or more. The group IIIb element or elements include Ga, Al, or both of Ga and Al.

A method for manufacturing a photoelectric conversion device of an embodiment has a first step of depositing a group Ib element or elements and a group VIb element or elements on a bottom electrode being heated at 200° C. to 400° C., a second step of, after the first step, depositing a group IIIb element or elements and a group VIb element or elements on the product with the elements of groups Ib and VIb deposited in the first step, a third step of, after the second step, depositing a group Ib element or elements and a group VIb element or elements on the product with the elements of groups IIIb and VIb deposited in the second step, while heating the product at 450° C. to 550° C., and a fourth step of, after the third step, cooling, to 400° C. or lower, the product with the elements of groups Ib and VIb deposited in the third step and then depositing a group IIIb element or elements and a group VIb element or elements on the product. The group VIb element or elements include Ga, Al, or both of Ga and Al.

A method for manufacturing a solar cell of an embodiment has a first step of depositing a group Ib element or elements and a group VIb element or elements on a bottom electrode being heated at 200° C. to 400° C., a second step of, after the first step, depositing a group IIIb element or elements and a group VIb element or elements on the product with the elements of groups Ib and VIb deposited in the first step, a third step of, after the second step, depositing a group Ib element or elements and a group VIb element or elements on the product with the elements of groups IIIb and VIb deposited in the second step, while heating the product at 450° C. to 550° C., and a fourth step of, after the third step, cooling, to 400° C. or lower, the product with the elements of groups Ib and VIb deposited in the third step and then depositing a group IIIb element or elements and a group VIb element or elements on the product. The group VIb element or elements include Ga, Al, or both of Ga and Al.

Hereinafter, embodiments will be described in detail with reference to the drawings.

### (Thin Film Solar Cell)

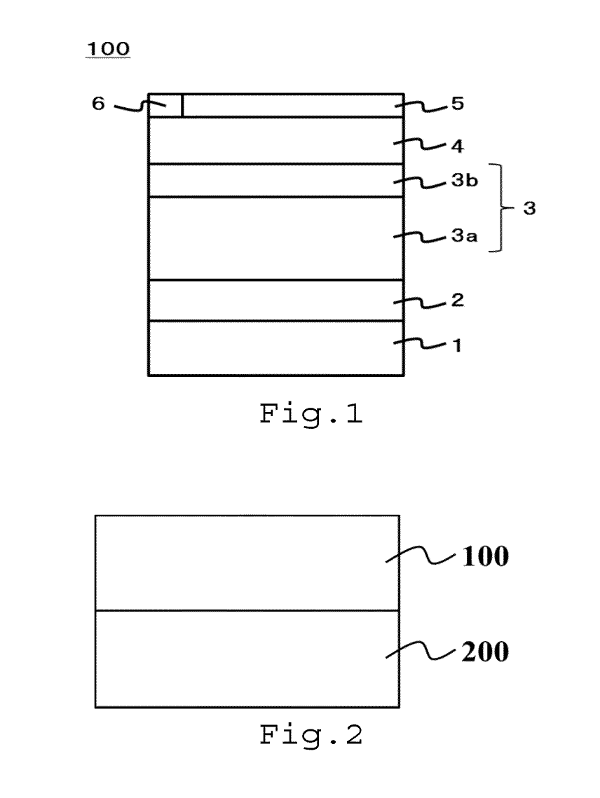

FIG. 1 is a schematic diagram showing a photoelectric conversion device 100 according to an embodiment. The photoelectric conversion device 100 includes a substrate 1; a bottom electrode 2 formed on the substrate 1; a light absorbing layer 3 including a p-type semiconductor layer 3a formed on the bottom electrode 2 and an n-type semiconductor layer 3b forming a homojunction with the p-type semiconductor layer 3a; a transparent electrode 4 formed on the light absorbing layer 3; a top electrode 5 formed on the transparent electrode 4; and an antireflective film 6 formed on the top electrode 5. The light absorbing layer 3 has the p-type semiconductor layer 3a on its bottom electrode 2 side and has the n-type semiconductor layer 3b on its top electrode 5 side. Specifically, the photoelectric conversion device 100 may be a solar cell. As shown in FIG. 2, which is a schematic cross-sectional view of a multi-junction photoelectric conversion device, the photoelectric conversion device 100 of an embodiment may be joined to another photoelectric conversion device 200 to form a multi-junction device. The light absorbing layer of the photoelectric conversion device 100 preferably has a band gap wider than that of the light absorbing layer of the photoelectric conversion device 200. For example, Si is used to form the light absorbing layer of the photoelectric conversion device 200.

(Substrate)

In an embodiment, the substrate 1 is preferably made of Na-containing glass such as soda-lime glass, and alternatively, the substrate 1 may be made of a sheet of a metal such as stainless steel, Ti, or Cr, or a resin such as polyimide.

(Bottom Electrode)

In an embodiment, the bottom electrode 2 as an electrode of the photoelectric conversion device 100 is a metal film or a conductive oxide film formed on the substrate 1. The bottom electrode 2 may be a film of a conductive metal such as Mo or W or a transparent conductive film including indium tin oxide (ITO), silicon oxide, tin oxide, or the like. The bottom electrode 2 may also be a multilayer film including an ITO layer and a SnO₂ or TiO₂ thin film deposited thereon. To prevent the diffusion of impurities from the substrate 1, an extremely thin film of SiO₂ is preferably placed between the ITO and the substrate 1. The bottom electrode 2 preferably has an uppermost surface made of Mo. The bottom electrode 2 may be a multilayer structure of an extremely thin Mo film and a transparent conductive film. Examples of the multilayer structure of the bottom electrode 2 include Mo/SnO₂/ITO/SiO₂, Mo/SnO₂/TiO₂/ITO/SiO₂, Mo/TiO₂/SnO₂/ITO/SiO₂, and Mo/TiO₂/ITO/SiO₂. When the bottom electrode 2 is a film of a metal such as Mo or W, the thickness of the bottom electrode 2 is typically 500 nm to 1,000 nm. When the bottom electrode 2 has a multilayer structure, the thickness of each layer is typically 5 nm for Mo, 100 nm for SnO₂, 10 nm for TiO₂, 150 nm for ITO, and 10 nm for SiO₂. A compound Mo—X, wherein X is an element constituting the light absorbing layer (the element X is at least one selected from the group consisting of S, Se, and Te), is preferably formed on the surface of the thin Mo film, so that an ohmic contact with the light absorbing layer can be formed.

(Light Absorbing Layer)

In an embodiment, the light absorbing layer 3 is a photoelectric conversion layer of the photoelectric conversion device 100. The light absorbing layer 3 is also a semiconductor layer including the p-type and n-type compound semiconductor layers 3a and 3b with a homojunction therebetween. The light absorbing layer 3 may be a layer of a compound semiconductor including a group Ib element or elements, a group IIIb element or elements, exclusive of In, and a group VIb element or elements and having a chalcopyrite structure, such as CGS (CuGaSe₂), AGS (CuGaSe₂), CAGS ((Cu,Ag) GaSe₂), AGSS (CuGa (Se,S)₂), or AAGS (Ag(Al,Ga)Se₂). The group Ib element or elements preferably include Cu, Ag, or both of Cu and Ag. The group IIIb element or elements preferably include Ga, Al or both of Ga and Al. In an embodiment, therefore, the compound having a chalcopyrite structure and forming the light absorbing layer of the photoelectric conversion device 100 is free of In, although a CIGS light absorbing layer contains In. The group VIb element or elements preferably include at least one element selected from the group consisting of O, S, Se, and Te, more preferably include Se, S or both of Se and S. When the combination of the group Ib element, the group IIIb element, and the group VIb element is so controlled that the band gap Eg satisfies the relation 1.68≦Eg (eV)≦2.0, the resulting light absorbing layer can efficiently absorb short-wavelength light, which can widen the range of uses of the device as a top cell in a tandem structure.

Specifically, the light absorbing layer 3 may include a compound semiconductor such as CuGaSe₂, AgGaSe₂, (Ag,Cu) GaSe₂, CuGa(Se,S)₂, AgGa(Se,S)₂, (Ag,Cu)Ga(Se,S)₂, CuAlSe₂, AgAlSe₂, (Ag,Cu) AlSe₂, CuAl(Se,S)₂, AgAl(Se,S)₂, (Ag,Cu) Al(Se,S)₂, Cu(Ga,Al)Se₂, Ag(Ga,Al)Se₂, (Ag,Cu) (Ga,Al)Se₂, Cu(Ga,Al) (Se,S)₂, Ag(Ga,Al) (Se,S)₂, or (Ag,Cu) (Ga,Al) (Se,S)₂.

In an embodiment, the light absorbing layer 3 has the p-type compound semiconductor on the bottom electrode 2 side and has the n-type compound semiconductor on the transparent electrode 4 side. The light absorbing layer 3 typically has a thickness of 1,000 nm to 3,000 nm. For example, the p-type compound semiconductor layer 3a preferably has a thickness of 1,500 nm to 2,500 nm. The n-type compound semiconductor layer 3b preferably has a thickness of 50 nm to 500 nm.

In order to prevent recombination of generated carriers inside the light absorbing layer 3, the light absorbing layer 3 preferably has an average crystal grain size of 1.5 μm or more, more preferably 2 μm or more. The average crystal grain size is not more than the thickness of the light absorbing layer 3. This is because if there are a large number of grain boundaries in the thickness direction of the light absorbing layer 3, the recombination of generated carriers can be less effectively prevented. Even when In is not used as the group IIIb element, the light absorbing layer 3 with large grain sizes can be formed using the new three-stage method.

The average crystal grain size of the light absorbing layer 3 can be determined from a cross-sectional scanning electron microscope (SEM) image of the photoelectric conversion device 100, its grain size map obtained by electron back scatter diffraction (EBSD) analysis, and its grain distribution chart obtained by EBSD analysis. The cross-section of the light absorbing layer 3 is observed with an SEM at a magnification of 20,000 times, and the average crystal grain size is estimated from the EBSD measurements of the observed region. In the SEM and EBSD measurements, the central part-containing cross-section of the photoelectric conversion device 100 is observed in the thickness direction. The process of determining the average crystal grain size includes dividing the cross-section of the light absorbing layer 3 into 10 regions in the width direction; and observing grains in a field of view in each region to determine the average crystal grain size in each region, wherein the field of view corresponds to a part of the light absorbing layer 3 extending from the bottom electrode 2 side and having a thickness of ¼ of the thickness of the light absorbing layer 3. Subsequently, the maximum and minimum values are excluded from the average crystal grain sizes of the respective measured regions, and the average crystal grain size of the light absorbing layer 3 is determined from the resulting eight average values.

The distribution of the concentration of the group IIIb element in the light absorbing layer 3 is determined using secondary ion mass spectrometry (SIMS) analysis. When the light absorbing layer 3 is deposited by the three-stage method, the deposition of Cu or Ag and Se or S (0-th stage) before the first stage deposition allows the IIIb element to interdiffuse easily, which narrows the width of the distribution of IIIb element concentrations in the light absorbing layer 3. The SIMS analysis is performed in the thickness direction on the central part of the photoelectric conversion device 100. Ga concentrations in the thickness direction of the light absorbing layer 3 are nominally determined as secondary ion intensity ratios by SIMS. The secondary ion intensities to be used are the values obtained from the inside of the light absorbing layer 3, which is at least 200 nm inside from each interface. The maximum value I_{MAX} and the minimum value I_{MIN} of the Ga secondary ion intensity in the light absorbing layer 3 are determined, and I_{MIN}/I_{MAX} is calculated. The photoelectric conversion device 100 of an embodiment satisfies I_{MIN}/I_{MAX}≧0.7 because Ga is well diffused in the light absorbing layer even when it is free of In. I_{MIN} and I_{MAX} preferably satisfy I_{MIN}/I_{MAX}≦0.9. I_{MIN} and I_{MAX} more preferably satisfy I_{MIN}/I_{MAX}≧0.8. I_{MIN} and I_{MAX} even more preferably satisfy 0.8≦I_{MIN}/I_{MAX}≦0.9.

Next, it will be described how to produce the light absorbing layer 3 according to an embodiment.

In an embodiment, the light absorbing layer 3 is obtained by a process that includes forming a p-type semiconductor layer as a precursor on the bottom electrode 2 and converting a region of the p-type semiconductor layer to an n-type layer, wherein the region is on the side where the transparent electrode 4 is to be formed. The method of forming the p-type semiconductor layer may be an advanced version of a vapor deposition method (three-stage method) including a rapid cooling step between its second and third stages. In an embodiment, the new three-stage method includes a first step of depositing a group Ib element or elements and a group VIb element or elements on the bottom electrode 2 being heated at 200° C. to 400° C. (0-th stage); a second step of, after the first step, depositing a group IIIb element or elements and a group VIb element or elements on the product with the elements of groups Ib and VIb deposited in the first step (first stage); a third step of, after the second step, depositing a group Ib element or elements and a group VIb element or elements on the product with the elements of groups IIIb and VIb deposited in the second step, while heating the product at 450° C. to 550° C. (second stage); and a fourth step of, after the third step, cooling, to 400° C. or lower, the product with the elements of groups Ib and VIb deposited in the third step and then depositing a group IIIb element or elements and a group VIb element or elements on the product (third stage). The new three-stage method may further include a fifth step of, between the second and third steps, depositing a group Ib element or elements and a group VIb element or elements on the product with the elements of groups IIIb and VIb deposited in the second step (1.5-th stage), wherein in the third step, the group Ib element or elements and the group VIb element or elements may be deposited on the product with the elements of groups Ib and VIb deposited in the fifth step.

In the new three-stage method, first, the substrate (a member composed of the substrate 1 and the bottom electrode 2 formed thereon) is heated to a temperature of 200° C. to 400° C., and a group Ib element such as Cu or Ag and a group VIb element such as Se or S are deposited on the substrate (0-th stage). Subsequently, a group IIIb element such as Ga or Al and a group VIb element such as Se or S are deposited (first stage). If necessary, a group Ib element such as Cu or Ag and a group VIb element such as Se or S are deposited again (1.5-th stage).

Subsequently, the substrate is heated to a temperature of 450° C. to 550° C., and a group Ib element such as Cu or Ag and a group VIb element such as Se or S are deposited. The start of an endothermic reaction is checked, and the deposition of the group Ib element Cu or Ag is stopped once when the composition has an excess of the group Ib element Cu or Ag (second stage).

Immediately after the deposition is stopped, the substrate is rapidly cooled by natural cooling or by locally spraying an inert gas such as nitrogen or argon, so that the substrate is cooled to a temperature of 400° C. or lower. After the rapid cooling, a group IIIb element such as Ga or Al and a group VIb element such as Se or S are deposited again (third stage) to form a composition with a slight excess of the group IIIb element Ga or Al.

When containing In as a group IIIb element, the light absorbing layer 3 deposited by the conventional three-stage method can have large grain sizes so that the recombination of generated carriers can be prevented. This is because In and Cu can easily interdiffuse so that the growth of large-size grains can be facilitated via a Cu—Se liquid phase (second stage). On the other hand, the light absorbing layer 3 free of In and including Ga or Al as a group IIIb element and a group VIb element such as Se or S tends to have small grain sizes because Ga or Al and Cu or Ag hardly interdiffuse. Therefore, Cu or Ag and Se or S are deposited before or during the first stage deposition of Ga or Al and Se or S, so that the diffusion lengths of Ga or Al and Cu or Ag can be shortened, which makes it possible even for the light absorbing layer 3 not containing In as the group IIIb element to have large grain sizes when the second stage and later stages are subsequently performed. If the photoelectric conversion layer including the In-free compound semiconductor layer with a chalcopyrite structure is formed by the conventional three-stage method, large grain sizes (an average crystal grain size of 1.5 μm or more) cannot be obtained, and the relation I_{MIN}/I_{MAX}≧0.7 cannot be satisfied, because the group IIIb element is less diffusible. The new three-stage method can achieve the relation I_{MIN}/I_{MAX}≧0.7 because it includes the 0-th stage and the 1.5-th stage described above. The compound of Cu or Ag and Se or S has a low melting point and is difficult to deposit at a high temperature. Therefore, the substrate temperature is preferably from 200° C. to 400° C. at the 0-th stage and the 1.5-th stage.

The process described above allows the bottom electrode 2-side part of the light absorbing layer 3 to have large crystal grain sizes. The rapid cooling after the completion of the second-stage deposition allows the transparent electrode 4-side part of the light absorbing layer 3 to have small grain sizes or to be amorphous. In addition, the rapid cooling followed by the third-stage deposition at low temperature can suppress the diffusion of the group Ib element Cu or Ag, so that the transparent electrode 4-side part of the light absorbing layer 3 can contain many Cu or Ag vacancies as compared with when the rapid cooling is not performed. When n-type doping is performed on the product with many Cu or Ag vacancies, a large amount of the n-type dopant can enter the Cu or Ag vacancy sites, which is advantageous in that the doped region can function as an n-type-dopant-rich n-type semiconductor. After the p-type semiconductor layer is formed, part of the p-type semiconductor layer can be converted from the p-type to the n-type by liquid-phase doping with a solution containing an n-type dopant such as Cd or Zn (e.g., cadmium sulfate). When part of the p-type semiconductor layer is converted to the n-type, a homojunction-type light absorbing layer 3 is formed, which has a homojunction between the p-type compound semiconductor layer 3a and the n-type compound semiconductor layer 3b. The doping process may be performed in such a manner that the concentration of the n-dopant is higher on the side where the transparent electrode 4 is to be formed. The doping with the n-dopant is preferably followed by washing off the dopant with water before the next step is performed.

(Transparent Electrode)

In an embodiment, the transparent electrode 4 is a film electrically conductive and transparent for light such as sunlight. For example, the transparent electrode 4 may include ZnO:Al containing 2 wt % of alumina (Al₂O₃) or include ZnO:B containing B as a dopant derived from diborane. A semi-insulating layer, such as an i-ZnO layer, for serving as a protective layer may also be formed, for example, with a thickness of about 20 nm to about 100 nm between the transparent electrode 4 and the light absorbing layer 3. The transparent electrode 4 can be formed by sputtering or other deposition techniques.

(Top Electrode)

In an embodiment, the top electrode 5 as an electrode of the photoelectric conversion device 100 is a metal film formed on the transparent electrode 4. The top electrode 5 may include Al, Ag, Au, or the like. Al, Ag, Au, or the like may be deposited on a Ni or Cr film formed on the transparent electrode 4 by deposition so that the adhesion of the top electrode to the transparent electrode 4 can be increased. The top electrode 5 typically has a thickness of 300 nm to 1,000 nm. For example, the top electrode 5 can be deposited by resistance heating vapor deposition. If necessary, the top electrode 5 may be omitted.

(Antireflective Film)

In an embodiment, the antireflective film 6 is a film provided to facilitate the introduction of light into the light absorbing layer 3. The antireflective film 6 is formed on the transparent electrode 4. For example, the antireflective film 6 preferably includes MgF₂. The antireflective film 6 typically has a thickness of 90 nm to 120 nm. For example, the antireflective film 6 can be formed by electron beam vapor deposition. If necessary, the antireflective film 6 may be omitted.

### EXAMPLES

Hereinafter, embodiments will be more specifically described with reference to examples.

### Example 1

Soda-lime glass was used as the substrate 1, and a Mo thin film with a thickness of about 700 nm was deposited by sputtering to form the bottom electrode 2 on the substrate 1. The sputtering was performed in an Ar gas atmosphere under application of 200 W RF using a Mo target. After the Mo thin film was deposited to form the bottom electrode 2, a CuGa_{0.74}Al_{0.26}Se₂ thin film was deposited by the new three-stage method to form the light absorbing layer 3. First, the substrate was heated to a temperature of 300° C., and Cu and Se were deposited thereon (0-th stage). Subsequently, Ga, Al, and Se were deposited thereon (first stage). Subsequently, the substrate was heated to a temperature of 500° C., and Cu and Se were deposited thereon. The start of an endothermic reaction was checked, and the deposition of Cu was stopped once when the composition had an excess of Cu (second stage). Immediately after the deposition was stopped, the substrate was rapidly cooled to a temperature of 400° C. by natural cooling. After the rapid cooling, Ga, Al, and Se were deposited again (third stage) to form a composition with a slight excess of the group IIIb element Ga or Al. The light absorbing layer 3 was formed with a thickness of about 2,000 nm. In the light absorbing layer, the small grain size layer had a thickness of about 200 nm.

The product obtained after the deposition of the light absorbing layer 3 was immersed in a 0.8 mM cadmium sulfate solution and allowed to react at 80° C. for 22 minutes so that part of the light absorbing layer 3 was converted to an n-type layer. Thus, an about 100-nm-thick, n-type semiconductor layer 3b doped with Cd was formed as a front-side part of the light absorbing layer 3. A semi-insulating layer of an i-ZnO thin film for serving as a protective film was deposited on the n-type semiconductor layer 3b by spin coating. Subsequently, ZnO:Al containing 2 wt % of alumina (Al₂O₃) for serving as the transparent electrode 4 was deposited with a thickness of about 1 μm on the protective film. Al was further deposited as the top electrode 5 by resistance heating. The Al thickness was about 300 nm. Finally, a MgF₂ film with a thickness of about 100 nm was deposited as the antireflective film 6 by electron beam vapor deposition. In this way, the photoelectric conversion device 100 of an embodiment was obtained.

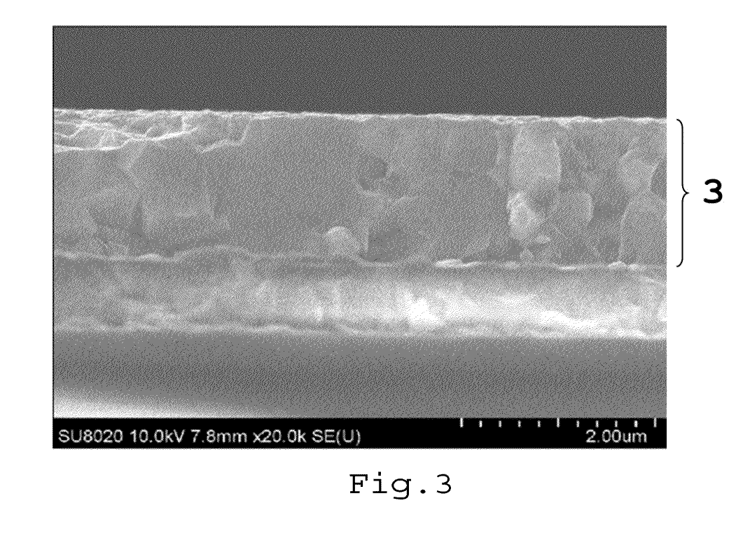

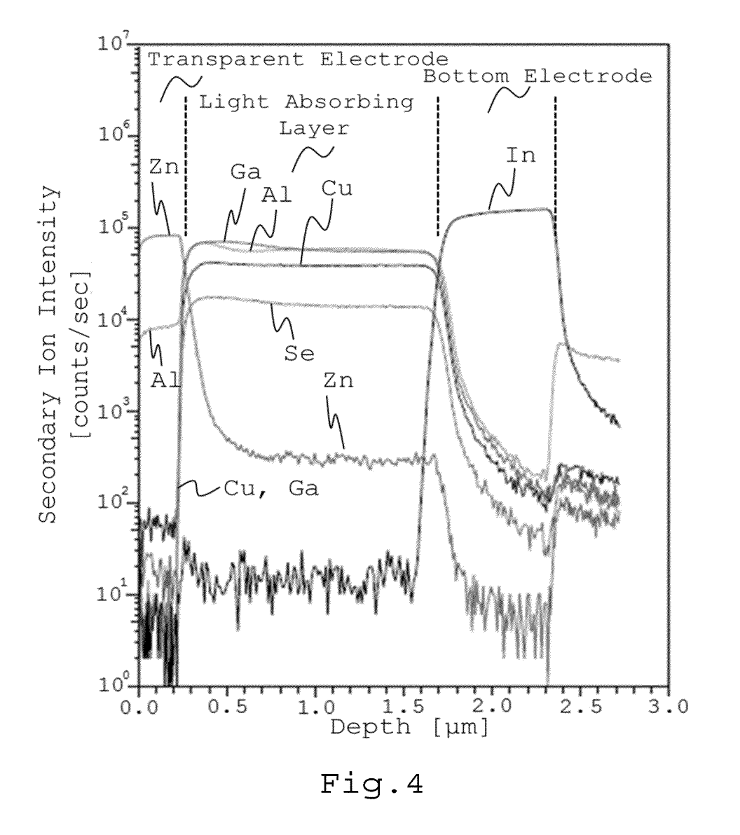

The light absorbing layer 3 of the resulting photoelectric conversion device 100 was measured for average crystal grain size. The average crystal grain size was determined from the cross-sectional SEM image of FIG. 3 by the method described above. The resulting average crystal grain size was 1,500 nm. SIMS analysis was performed, in which the Ga and Al concentrations were determined from the SIMS counts, and the concentrations of the group IIIb element in the light absorbing layer 3 were determined, from which the maximum and minimum values were selected. FIG. 4 shows the results of the SIMS analysis in Example 1.

The open circuit voltage (Voc), the short-circuit current density (Jsc), and the fill factor (FF) were measured to calculate the conversion efficiency η. A voltage source and a multimeter were used under simulated sunlight AM 1.5 applied from a solar simulator. While the voltage from the voltage source was changed, the voltage at which the current was 0 mA under the simulated sunlight was measured to obtain the open circuit voltage (Voc). The current was measured when no voltage was applied, so that the short-circuit current density (Jsc) was obtained.

### Example 2

A photoelectric conversion device was prepared by the same process as in Example 1, except that only Ga was used as the group IIIb element for the light absorbing layer 3 so that a CuGaSe₂ thin film was deposited by the new three-stage method to form the light absorbing layer 3. The average crystal grain size and the conversion efficiency were then determined as in Example 1.

### Example 3

A photoelectric conversion device was prepared by the same process as in Example 2, except that Se and S were used as group VIb elements for the light absorbing layer 3 so that a CuGaSe_{0.58}S_{0.42} thin film was deposited by the new three-stage method to form the light absorbing layer 3. The average crystal grain size and the conversion efficiency were then determined as in Example 1.

### Example 4

A photoelectric conversion device was prepared by the same process as in Example 3, except that in addition to the 0-th stage step of depositing Cu and Se at a substrate temperature of 300° C., the step of depositing Cu and Se again (1.5-th stage) was performed during the first stage step of depositing Ga and Se in the process of depositing a CuGaSe_{0.58}S_{0.42} thin film by the new three-stage method to form the light absorbing layer 3. The average crystal grain size and the conversion efficiency were then determined as in Example 1.

### Example 5

A photoelectric conversion device was prepared by the same process as in Example 1, except that Ag was used as the group Ib element for the light absorbing layer 3 so that an AgGa_{0.74}Al_{0.26}Se₂ thin film was deposited by the new three-stage method to form the light absorbing layer 3. The average crystal grain size and the conversion efficiency were then determined as in Example 1.

### Example 6

A photoelectric conversion device was prepared by the same process as in Example 2, except that Ag was used as the group Ib element for the light absorbing layer 3 so that an AgGaSe₂ thin film was deposited by the new three-stage method to form the light absorbing layer 3. The average crystal grain size and the conversion efficiency were then determined as in Example 1.

### Example 7

A photoelectric conversion device was prepared by the same process as in Example 3, except that Ag was used as the group Ib element for the light absorbing layer 3 so that an AgGaSe_{0.82}S_{0.18} thin film was deposited by the new three-stage method to form the light absorbing layer 3. The average crystal grain size and the conversion efficiency were then determined as in Example 1.

### Example 8

A photoelectric conversion device was prepared by the same process as in Example 7, except that in addition to the 0-th stage step of depositing Ag and Se at a substrate temperature of 300° C., the step of depositing Ag and Se again (1.5-th stage) was performed during the first stage step of depositing Ga and Se in the process of depositing a AgGaSe_{0.82}S_{0.18} thin film by the new three-stage method to form the light absorbing layer 3. The average crystal grain size and the conversion efficiency were then determined as in Example 1.

### Comparative Examples 1 to 6

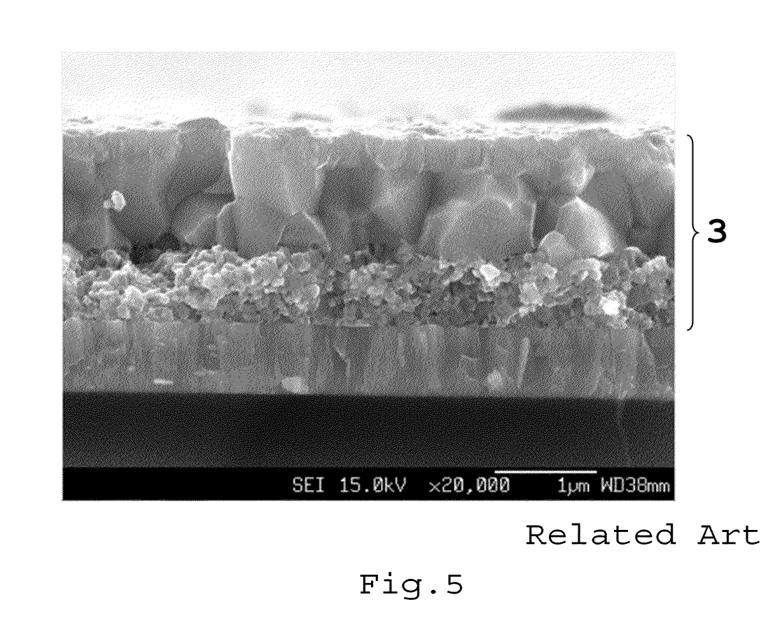

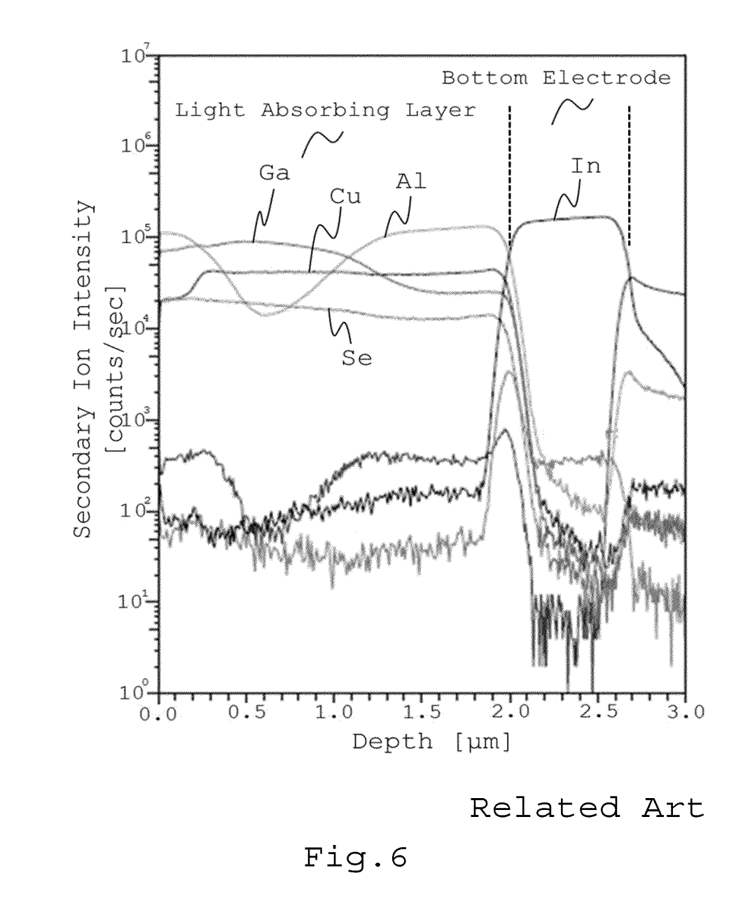

Photoelectric conversion devices were prepared by the same processes as those in Examples 1 to 6, respectively, except that the step of depositing Cu or Ag and Se or S (0-th stage) was not performed before the first stage step of depositing Ga or Al and Se or S in the process of depositing the light absorbing layer 3. The average crystal grain size and the conversion efficiency were then determined as in Example 1. The average crystal grain size in Comparative Example 1 was measured from the cross-sectional SEM image of FIG. 5 by the method described above. SIMS analysis was performed, in which the Ga and Al concentrations were determined from the SIMS counts, and the concentrations of the group IIIb element in the light absorbing layer 3 were determined, from which the maximum and minimum values were selected. FIG. 6 shows the results of the SIMS analysis in Comparative Example 1.

The conversion efficiency (η=Voc·Jsc·FF·100[%]) of each of the photoelectric conversion devices of the examples and the comparative examples is shown in the table below. The value of the average crystal grain size is rounded off to one significant figure. In the table, A represents the case where the 0-th stage is performed, B the case where the 0-th and 1.5-th stages are performed, and C the case where neither the 0-th stage nor the 1.5-th stage is performed.

TABLE 1A

| | 0-th | Constituent elements of |
|---|---|---|
| | stage | light absorbing layer |
| Example 1 | A | Cu(Al, Ga)Se₂ |
| Example 2 | A | CuGaSe₂ |
| Example 3 | A | CuGa(Se, S)₂ |
| Example 4 | B | CuGa(Se, S)₂ |
| Example 5 | A | Ag(Al, Ga)Se₂ |
| Example 6 | A | AgGaSe₂ |
| Example 7 | A | AgGa(Se, S)₂ |
| Example 8 | B | AgGa(Se, S)₂ |
| Comparative | C | Cu(Al, Ga)Se₂ |
| Example 1 | | |
| Comparative | C | CuGaSe₂ |
| Example 2 | | |
| Comparative | C | CuGa(Se, S)₂ |
| Example 3 | | |
| Comparative | C | Ag(Al, Ga)Se₂ |
| Example 4 | | |
| Comparative | C | AgGaSe₂ |
| Example 5 | | |
| Comparative | C | AgGa(Se, S)₂ |
| Example 6 | | |

TABLE 1B

| | Grain size (nm) | [Minimum]/[maximum] | Conversion |
|---|---|---|---|
| | of light | for Ga element | efficiency |
| | absorbing layer 3 | concentration | (%) |
| Example 1 | 1500 | 0.7 | 6 |
| Example 2 | 1800 | 0.8 | 10 |
| Example 3 | 1500 | 0.8 | 6 |
| Example 4 | 2000 | 0.85 | 8 |
| Example 5 | 1500 | 0.75 | 5 |
| Example 6 | 1800 | 0.85 | 8 |
| Example 7 | 1500 | 0.85 | 5 |
| Example 8 | 2000 | 0.9 | 7 |
| Comparative | 350 | 0.25 | 1 |
| Example 1 | | | |
| Comparative | 700 | 0.3 | 3 |
| Example 2 | | | |
| Comparative | 700 | 0.3 | 1 |
| Example 3 | | | |
| Comparative | 500 | 0.35 | 1 |
| Example 4 | | | |
| Comparative | 800 | 0.35 | 2 |
| Example 5 | | | |
| Comparative | 500 | 0.4 | 1 |
| Example 6 | | | |

In the process of depositing the light absorbing layer 3 by the three-stage method, the deposition of Cu or Ag and Se or S (0-th stage) before the first stage deposition allowed Ga or Al and Ag or Cu to easily interdiffuse, so that the growth of large-size grains was facilitated via a liquid phase, which resulted in the reduction of bulk defects and thus the improvement of the conversion efficiency. The rate of interdiffusion with a group Ib element decreases in the order In>>Ga>Al. Therefore, as the amount of Al increases, it becomes difficult to increase the grain size. Nevertheless, the process of depositing the light absorbing layer 3, shown in the examples, enabled the increase of the grain size. In the comparative examples, the group IIIb element was less diffusible, and the light absorbing layer was found to be separated into two sub-layers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photoelectric conversion device comprising:
a bottom electrode; and
a light absorbing layer on the bottom electrode,
wherein the light absorbing layer comprises a thin film of a semiconductor comprising a group Ib element or elements, a group IIIb element or elements, and a group VIb element or elements and having a chalcopyrite structure,
the light absorbing layer has an average crystal grain size of 1.5 μm or more, and
the group IIIb element or elements include Ga, Al, or both of Ga and Al.

2. The device according to claim 1,
wherein I_{MIN} and I_{MAX} satisfy the relation I_{MIN}/I_{MAX}≧0.7, and
wherein I_{MIN} is minimum value among group IIIb element concentrations in the thickness direction of the light absorbing layer, and I_{MAX} is maximum value among group IIIb element concentrations in the thickness direction of the light absorbing layer.

3. The device according to claim 1,
wherein I_{MIN} and I_{MAX} satisfy the relation I_{MIN}/I_{MAX}≧0.8, and
wherein I_{MIN} is minimum value among group IIIb element concentrations in the thickness direction of the light absorbing layer, and I_{MAX} is maximum value among group IIIb element concentrations in the thickness direction of the light absorbing layer.

4. The device according to claim 1,
wherein I_{MIN} and I_{MAX} satisfy the relation I_{MIN}/I_{MAX}≦0.9, and
wherein I_{MIN} is minimum value among group IIIb element concentrations in the thickness direction of the light absorbing layer, and I_{MAX} is maximum value among group IIIb element concentrations in the thickness direction of the light absorbing layer.

5. The device according to claim 1,
wherein the group Ib element or elements include Cu, Ag, or both of Cu and Ag, and
the group VIb element or elements include Se, S, or both of Se and S.

6. The device according to claim 1,
wherein the light absorbing layer is a semiconductor layer comprising p-type and n-type layers with a homojunction therebetween.

7. A solar cell comprising a photoelectric conversion device, the photoelectric conversion device comprising:
a bottom electrode; and
a light absorbing layer on the bottom electrode,
wherein the light absorbing layer comprises a thin film of a semiconductor comprising a group Ib element or elements, a group IIIb element or elements, and a group VIb element or elements and having a chalcopyrite structure,
the light absorbing layer has an average crystal grain size of 1.5 μm or more, and
the group IIIb element or elements include Ga, Al, or both of Ga and Al.

8. The cell according to claim 7,
where I_{MIN} is minimum value among group IIIb element concentrations in the thickness direction of the light absorbing layer, and I_{MAX} is maximum value among group IIIb element concentrations in the thickness direction of the light absorbing layer,
I_{MIN} and I_{MAX} satisfy the relation I_{MIN}/I_{MAX}≧0.7.

9. The cell according to claim 7,
where I_{MIN} is minimum value among group IIIb element concentrations in the thickness direction of the light absorbing layer, and I_{MAX} is maximum value among group IIIb element concentrations in the thickness direction of the light absorbing layer,
I_{MIN} and I_{MAX} satisfy the relation I_{MIN}/I_{MAX}0.8.

10. The cell according to claim 7,
where I_{MIN} is minimum value among group IIIb element concentrations in the thickness direction of the light absorbing layer, and I_{MAX} is maximum value among group IIIb element concentrations in the thickness direction of the light absorbing layer,
I_{MIN} and I_{MAX} satisfy the relation I_{MIN}/I_{MAX}≦0.9.

11. The cell according to claim 7,
wherein the group Ib element or elements include Cu, Ag, or both of Cu and Ag, and
the group VIb element or elements include Se, S, or both of Se and S.

12. The cell according to claim 7, wherein the light absorbing layer is a semiconductor layer comprising p-type and n-type layers with a homojunction therebetween.

13. A method for manufacturing a photoelectric conversion device, the method comprising:
a first step of depositing a group Ib element or elements and a group VIb element or elements on a bottom electrode being heated at 200° C. to 400° C.;
a second step of, after the first step, depositing a group IIIb element or elements and a group VIb element or elements on the product with the elements of groups Ib and VIb deposited in the first step;
a third step of, after the second step, depositing a group Ib element or elements and a group VIb element or elements on the product with the elements of groups IIIb and VIb deposited in the second step, while heating the product at 450° C. to 550° C.; and
a fourth step of, after the third step, cooling, to 400° C. or lower, the product with the elements of groups Ib and VIb deposited in the third step and then depositing a group IIIb element or elements and a group VIb element or elements on the product,
wherein the group VIb element or elements include Ga, Al, or both of Ga and Al.

14. The method according to claim 13, further comprising a fifth step of, between the second and third steps, depositing a group Ib element or elements and a group VIb element or elements on the product with the elements of groups IIIb and VIb deposited in the second step,
wherein in the third step, the group Ib element or elements and the group VIb element or elements are deposited on the product with the elements of groups Ib and VIb deposited in the fifth step.

15. The method according to claim 13,
wherein the group Ib element or elements include Cu, Ag, or both of Cu and Ag,
the group VIb element or elements include Se, S, or both of Se and S.

16. The method according to claim 14, wherein the fifth step comprises setting a substrate temperature at 200° C. to 400° C.
